(19) United States
(12) Patent Application Publication
(10) Pub. No.: US 2025/0166896 A1
(43) Pub. Date: May 22, 2025

(54) MULTILAYER ELECTRONIC COMPONENT AND BOARD HAVING MULTILAYER ELECTRONIC COMPONENT MOUNTED THEREON

(71) Applicant: SAMSUNG ELECTRO-MECHANICS CO., LTD., Suwon-si (KR)

(72) Inventors: Jeong Pil JHUN, Suwon-si (KR); Hwi Dae KIM, Suwon-si (KR); Soo Hwan SON, Suwon-si (KR); Young Ghyu AHN, Suwon-si (KR); Min Sik WOO, Suwon-si (KR)

(73) Assignee: SAMSUNG ELECTRO-MECHANICS CO., LTD., Suwon-si (KR)

(21) Appl. No.: 18/911,474

(22) Filed: Oct. 10, 2024

(30) Foreign Application Priority Data
Nov. 21, 2023 (KR) 10-2023-0162659

(51) Int. Cl. H01G 2/06; H01G 4/008; H01G 4/012; H01G 4/12; H01G 4/232; H01G 4/30

(52) U.S. Cl. CPC H01G 2/065; H01G 4/008; H01G 4/012; H01G 4/12; H01G 4/232; H01G 4/30

(57) ABSTRACT

A multilayer electronic component includes a body having an octahedral shape, the body including a dielectric layer and an internal electrode. The internal electrode includes a first internal electrode in contact with the first and third edge surfaces, and a second internal electrode in contact with the second and fourth edge surfaces. The external electrode includes first and third external electrodes respectively disposed on the first and third edge surfaces to be in contact with the first internal electrode, and second and fourth external electrodes respectively disposed on the second and fourth edge surfaces to be in contact with the second internal electrode.

### CROSS-REFERENCE TO RELATED APPLICATION(S)

This application claims benefit of priority to Korean Patent Application No. 10-2023-0162659 filed on Nov. 21, 2023 in the Korean Intellectual Property Office, the disclosure of which is incorporated herein by reference in its entirety.

### TECHNICAL FIELD

The present disclosure relates to a multilayer electronic component and a board having the same mounted thereon.

A multilayer ceramic capacitor (MLCC), a multilayer electronic component, is a chip-type condenser mounted on the printed circuit boards of various types of electronic products such as imaging devices, including a liquid crystal display (LCD) and a plasma display panel (PDP), computers, smartphones, and mobile phones, and serves to charge or discharge electricity therein or therefrom.

The multilayer ceramic capacitor may be used as a component of various electronic devices due to having a small size, ensuring high capacitance and being easily mounted. With the miniaturization and high-output power of various electronic devices such as computers and mobile devices, demand for miniaturization and implementation of high capacitance of multilayer ceramic capacitors has also been increasing.

MLCCs have also been widely used for decoupling that removes noise from electrical signals within a set due to low equivalent series inductance (ESL), and excellent high-frequency properties.

In order to address noise in high-speed integrated circuits (ICs), land surface capacitors (LSCs) may be applied to portions adjacent to the ICs. It is known that an LSC requires low thickness and high-frequency properties. In order to reduce ESL, it is important to minimize the number of magnetic flux linkages per unit current in a high-frequency region. Such an issue has been addressed in various manners, such as controlling the formation and structure in a way that minimizes a current path or a current loop, or disposing internal and external electrodes in a manner cancelling a magnetic field.

In general, LSCs may be disposed on a lower portion of an IC board, and thus may be required to have low thickness and low ESL properties. In this case, LSCs may be mounted in a position in which a solder ball on a lower portion of a board is removed. Low inductance ceramic capacitors (LICCs) have been mainly used. However, there is increasing need for capacitors having a square form-factor.

### SUMMARY

An aspect of the present disclosure aspect of the present disclosure is to provide a multilayer electronic component having improved high-frequency properties (low ESL) by reducing a current path of the multilayer electronic component.

Another aspect of the present disclosure is to improve equivalent series resistance (ESR) and equivalent series inductance (ESL) by minimizing a bottleneck portion of an internal electrode in a region in which the internal electrode and an external electrode are in contact with each other.

Another aspect of the present disclosure is to improve reliability of a multilayer electronic component by uniformly coating an internal electrode to reduce errors in a manufacturing process.

However, the aspects of the present disclosure are not limited to those set forth herein, and will be more easily understood in the course of describing specific example embodiments of the present disclosure.

According to an aspect of the present disclosure, there is provided a multilayer electronic component including a body including a dielectric layer and an internal electrode disposed alternately with the dielectric layer in a first direction, the body having first and second surfaces opposing each other in the first direction, third and fourth surfaces opposing each other in a second direction, crossing the first direction, and fifth and sixth surfaces opposing each other in a third direction, crossing the first and second directions, the body having a first edge surface connected to the first to third and fifth surfaces, a second edge surface connected to the first, second, fourth and fifth surfaces, a third edge surface connected to the first, second, fourth and sixth surfaces and opposing the first edge surface, and a fourth edge surface connected to the first, second, third and sixth surfaces and opposing the second edge surface, and an external electrode disposed on the body. The internal electrode may include a first internal electrode in contact with the first and third edge surfaces, and a second internal electrode in contact with the second and fourth edge surfaces. The external electrode may include first and third external electrodes respectively disposed on the first and third edge surfaces to be in contact with the first internal electrode, and second and fourth external electrodes respectively disposed on the second and fourth edge surfaces to be in contact with the second internal electrode.

According to another aspect of the present disclosure, there is provided a board having a multilayer electronic component mounted thereon, the board including a printed circuit board, a multilayer electronic component disposed on the printed circuit board, and a solder ball disposed on the printed circuit board, the solder ball surrounding the multilayer electronic component. The multilayer electronic component may include a body including a dielectric layer and an internal electrode disposed alternately with the dielectric layer in a first direction, the body having first and second surfaces opposing each other in the first direction, third and fourth surfaces opposing each other in a second direction, crossing the first direction, and fifth and sixth surfaces opposing each other in a third direction, crossing the first and second directions, the body having a first edge surface connected to the first to third and fifth surfaces, a second edge surface connected to the first, second, fourth and fifth surfaces, a third edge surface connected to the first, second, fourth and sixth surfaces and opposing the first edge surface, and a fourth edge surface connected to the first, second, third and sixth surfaces and opposing the second edge surface, and an external electrode disposed on the body. The internal electrode may include a first internal electrode in contact with the first and third edge surfaces, and a second internal electrode in contact with the second and fourth edge surfaces. The external electrode may include first and third external electrodes respectively disposed on the first and third edge surfaces to be in contact with the first internal electrode, and second and fourth external electrodes respectively disposed on the second and fourth edge surfaces to be in contact with the second internal electrode.

The multilayer electronic component may have improved high-frequency properties (low ESL) by reducing a current path of the multilayer electronic component.

ESR and ESL may be improved by minimizing a bottleneck portion of an internal electrode in a region in which the internal electrode and an external electrode are in contact with each other.

The multilayer electronic component may have improved reliability by uniformly coating an internal electrode to reduce errors in a manufacturing process.

However, the aspects of the present disclosure are not limited to those set forth herein, and will be more easily understood in the course of describing specific example embodiments of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic perspective view of a multilayer electronic component according to an example embodiment of the present disclosure;

FIG. 2 is a schematic exploded perspective view of a multilayer structure of an internal electrode;

FIG. 3A is a schematic cross-sectional view including a first internal electrode, and FIG. 3B is a schematic cross-sectional view including a second internal electrode;

FIG. 4 is a schematic plan view of laminated cross-sectional views including first and second internal electrodes;

FIG. 5A is a schematic design diagram of a cross-sectional view including a first internal electrode, and FIG. 5B is a schematic design diagram of a cross-sectional view including a second internal electrode; and

FIG. 6 is a schematic plan view of a board having a multilayer electronic component mounted thereon according to an example embodiment of the present disclosure.

### DETAILED DESCRIPTION

Hereinafter, example embodiments of the present disclosure are described with reference to the accompanying drawings. The present disclosure may, however, be exemplified in many different forms and should not be construed as being limited to the specific example embodiments set forth herein. In addition, example embodiments of the present disclosure may be provided for a more complete description of the present disclosure to those skilled in the art. Accordingly, the shapes and sizes of the elements in the drawings may be exaggerated for clarity of description, and elements denoted by the same reference numerals in the drawings may be the same elements.

In order to clearly illustrate the present disclosure, portions not related to the description are omitted, and sizes and thicknesses are magnified in order to clearly represent layers and regions, and similar portions having the same functions within the same scope are denoted by similar reference numerals throughout the specification. Throughout the specification, when an element is referred to as “comprising” or “including,” it means that it may include other elements as well, rather than excluding other elements, unless specifically stated otherwise.

In the drawings, a first direction may be defined as a lamination direction or a thickness (T) direction, a second direction may be defined as a length (L) direction, and a third direction may be defined as a width (W) direction.

### Multilayer Electronic Component

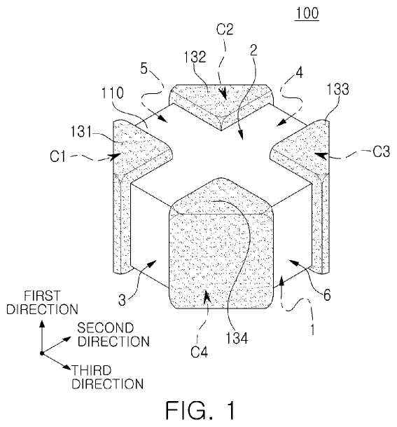

FIG. 1 is a schematic perspective view of a multilayer electronic component according to an example embodiment of the present disclosure.

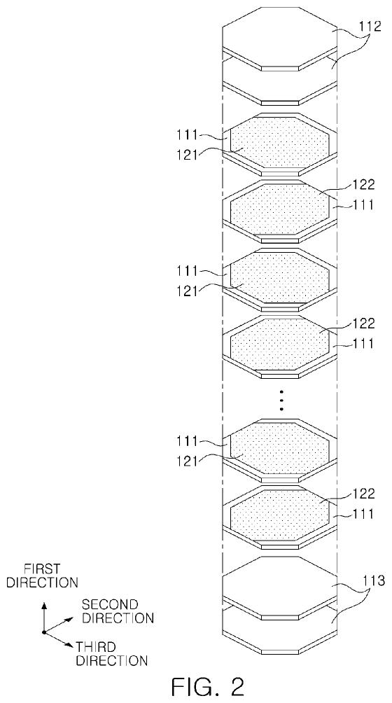

FIG. 2 is a schematic exploded perspective view of a multilayer structure of an internal electrode.

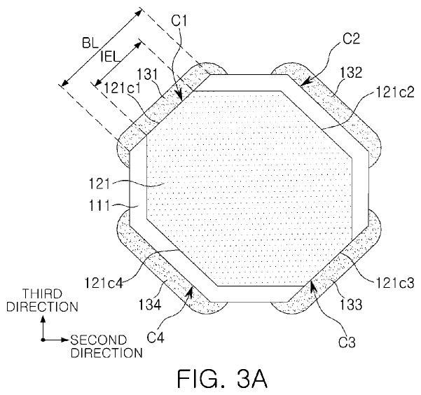

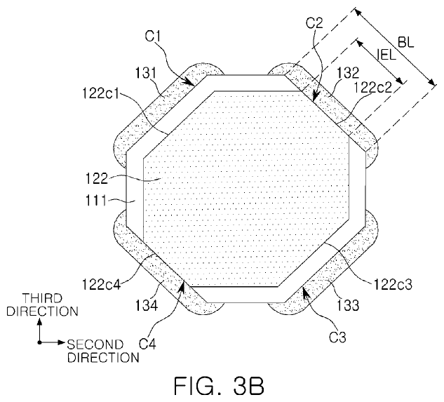

FIG. 3A is a schematic cross-sectional view including a first internal electrode, and FIG. 3B is a schematic cross-sectional view including a second internal electrode.

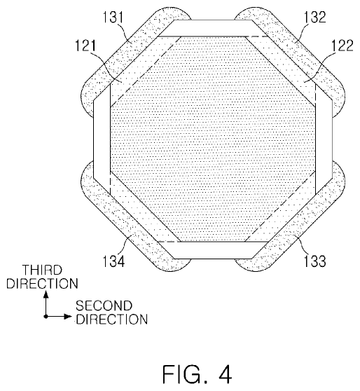

FIG. 4 is a schematic plan view of laminated cross-sectional views including first and second internal electrodes.

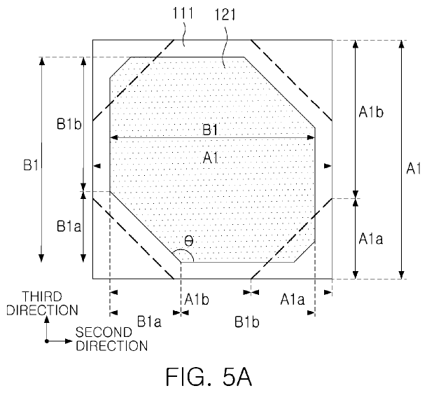

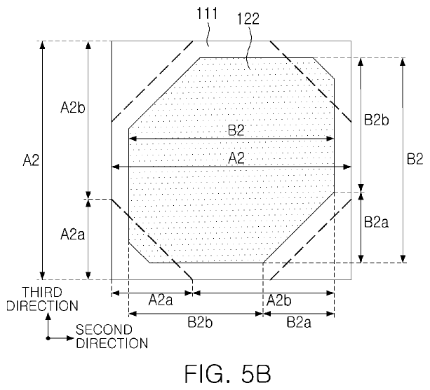

FIG. 5A is a schematic design diagram of a cross-sectional view including a first internal electrode, and FIG. 5B is a schematic design diagram of a cross-sectional view including a second internal electrode.

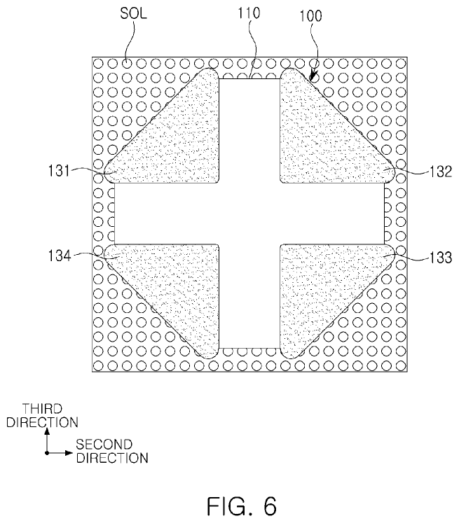

FIG. 6 is a schematic plan view of a board having a multilayer electronic component mounted thereon according to an example embodiment of the present disclosure.

Hereinafter, a multilayer electronic component and a board having the same mounted thereon according to an example embodiment of the present disclosure will be described in detail with reference to FIGS. 1 to 6. A multilayer ceramic capacitor is described as an example of a multilayer electronic component. However, the present disclosure may be applied to various electronic products using a dielectric composition, such as inductors, piezoelectric elements, varistors, thermistors, or the like.

A multilayer electronic component 100 according to an example embodiment of the present disclosure may include a body 110 including a dielectric layer 111 and internal electrodes 121 and 122 disposed alternately with the dielectric layer 111 in a first direction, the body 110 having first and second surfaces 1 and 2 opposing each other in the first direction, third and fourth surfaces 3 and 4 opposing each other in a second direction, perpendicular to the first direction, and fifth and sixth surfaces 5 and 6 opposing each other in a third direction, perpendicular to the first and second directions, the body 110 having a first edge surface C1 connected to the first to third and fifth surfaces 1, 2, 3, and 5, a second edge surface C2 connected to the first, second, fourth and fifth surfaces 1, 2, 4, and 5, a third edge surface C3 connected to the first, second, fourth and sixth surfaces 1, 2, 4, and 6, the third edge surface C3 opposing the first edge surface C1, and a fourth edge surface C4 connected to the first, second, third and sixth surfaces 1, 2, 3, and 6, the fourth edge surface C4 opposing the second edge surface C2, and external electrodes 131, 132, 133, and 134 disposed on the body 110. The internal electrodes 121 and 122 may include a first internal electrode 121 in contact with the first and third edge surfaces C1 and C3, and a second internal electrode 122 in contact with the second and fourth edge surfaces C2 and C4, and the external electrodes 131, 132, 133, and 134 may include first and third external electrodes 131 and 133 respectively disposed on the first and third edge surfaces C1 and C3, the first and third external electrodes 131 and 133 in contact with the first internal electrode 121, and second and fourth external electrodes 132 and 134 respectively disposed on the second and fourth edge surfaces C2 and C4, the second and fourth external electrodes 132 and 134 in contact with the second internal electrode 122.

In the body 110, the dielectric layer 111 and the internal electrodes 121 and 122 may be alternately laminated.

More specifically, the body 110 may include a capacitance formation portion disposed in the body 110, the capacitance formation portion including the first internal electrode 121 and the second internal electrode 122, in the first direction, with the dielectric layer 111 interposed therebetween, to form capacitance.

A specific shape of the body 110 is not particularly limited. However, as illustrated, the body 110 may have an octahedral shape or a shape similar thereto. During a sintering process, ceramic particles included in the body 110 may shrink, such that the body 110 may not have an octahedral shape having perfectly straight lines, but may have a substantially octahedral shape.

The body 110 may have first and second surfaces 1 and 2 opposing each other in a first direction, third and fourth surfaces 3 and 4 connected to the first and second surfaces 1 and 2, the third and fourth surfaces 3 and 4 opposing each other in a second direction, perpendicular to the first direction, and fifth and sixth surfaces 5 and 6 connected to the first and second surfaces 1 and 2, the fifth and sixth surfaces 5 and 6 not connected to the third and fourth surfaces 3 and 4, the fifth and sixth surfaces 5 and 6 opposing each other in a third direction, perpendicular to the first and second directions.

The body 110 may have a first edge surface C1 connected to the first to third and fifth surfaces 1, 2, 3, and 5, a second edge surface C2 connected to the first, second, fourth and fifth surfaces 1, 2, 4, and 5, a third edge surface C3 connected to the first, second, fourth and sixth surfaces 1, 2, 4, and 6, the third edge surface C3 opposing the first edge surface C1, and a fourth edge surface C4 connected to the first, second, third and sixth surfaces 1, 2, 3, and 6, the fourth edge surface C4 opposing the second edge surface C2.

That is, the first to fourth edge surfaces C1, C2, C3, and C4 may be spaced apart from each other.

In the present disclosure, “surface” may refer to all surfaces including the first to sixth surfaces 1, 2, 3, 4, 5, and 6 and the first to fourth edge surfaces C1, C2, C3, and C4. If necessary, the first to sixth surfaces 1, 2, 3, 4, 5, and 6 and the first to fourth edge surfaces C1, C2, C3, and C4 are separately described, but will be properly understood by those skilled in the art.

In addition, with respect to a cross-section of the body 110 in the second and third directions, the first to fourth edge surfaces C1, C2, C3, and C4 may not be substantially parallel to the second and third directions.

In the present disclosure “not substantially parallel” may mean that an angle formed by a line, a surface, and a direction and another line, another surface, and another direction is greater than 0° and less than 180°, specifically, 1° or more and 179° or less, more specifically, 5° or more and 175° or less. “Substantially parallel” may mean that there is an angle, formed by a line, a surface, and a direction and another line, another surface, and another direction, to be 1° or less, or more specifically, 5° or less, due to a process error or a measurement error recognizable by one of ordinary skill in the art, or may mean that a line, a surface, and a direction and another line, another surface, and another direction are parallel to each other.

For example, the first to fourth edge surfaces C1, C2, C3, and C4 not substantially parallel to the second and third directions may mean that with respect to the cross-section of the body 110 in the second and third directions, an angle formed by the first to fourth edge surfaces C1, C2, C3, and C4 and the second direction and angle formed by the first to fourth edge surfaces C1, C2, C3, and C4 and the third direction is greater than 0° and less than 180°, specifically, 1° or more and 179° and less, more specifically, 5° or more and 175° and less.

A plurality of dielectric layers 111, included in the body 110, may be in a sintered state, and adjacent dielectric layers 111 may be integrated with each other such that boundaries therebetween are not readily apparent without using a scanning electron microscope (SEM).

A raw material included in the dielectric layer 111 is not limited as long as sufficient capacitance is obtainable therewith. In general, a perovskite (ABO₃)-based material may be used. For example, a barium titanate-based material, a lead composite perovskite-based material, or a strontium titanate-based material may be used. The barium titanate-based material may include BaTiO₃-based ceramic particles. Examples of the ceramic particles may include (Ba₁₋ₓCaₓ)TiO₃ (0<x<1), Ba (Ti_{1-y}Ca_{y})O₃ (0<y<1), (Ba₁₋ₓCaₓ)(Ti_{1-y}Zr_{y})O₃ (0<x<1, 0<y<1), or Ba (Ti_{1-y}Zr_{y})O₃ (0<y<1) obtained by partially dissolving Ca or Zr in BaTiO₃.

In addition, the raw material, included in the dielectric layer 111, may be obtained by adding various ceramic additives, organic solvents, binders, dispersants, and the like to particles such as barium titanate (BaTiO₃) depending on the purpose of the present disclosure.

An average thickness of the dielectric layer 111 is not particularly limited.

In order to more easily achieve high capacitance and miniaturization of a multilayer electronic component, the average thickness of the dielectric layer 111 may be 1.0 μm or less, preferably 0.6 μm or less, and more preferably 0.4 μm or less.

Here, the thickness of the dielectric layer 111 may refer to a thickness of the dielectric layer 111 disposed between the first and second internal electrodes 121 and 122.

The thickness of the dielectric layer 111 may refer to a size of the dielectric layer 111 in the first direction. In addition, the thickness of the dielectric layer 111 may refer to an average thickness of the dielectric layer 111, and may refer to an average size of the dielectric layer 111 in the first direction.

The average size of the dielectric layer 111 in the first direction may be measured by scanning, with an SEM, an image of a cross-section of the body 110 in the first and second directions at a magnification of 10,000. More specifically, the average size of the dielectric layer 111 in the first direction may refer to an average value of sizes of one dielectric layer 111 in the first direction, measured at thirty points equally spaced apart from each other in the second direction, in the scanned image. The thirty equally spaced points may be designated in the capacitance formation portion. In addition, when such average value measurement is performed on ten dielectric layers 111, the average size of the dielectric layer 111 in the first direction may be further generalized.

The internal electrodes 121 and 122 may be disposed alternately with the dielectric layer 111 in the first direction.

The internal electrodes 121 and 122 may include a first internal electrode 121 and a second internal electrode 122. The first and second internal electrodes 121 and 122 may be alternately disposed to oppose each other, with the dielectric layer 111, included in the body 110, interposed therebetween. The first and second internal electrodes 121 and 122 may be electrically isolated from each other by the dielectric layer 111 interposed therebetween in the first direction.

Specifically, the internal electrodes 121 and 122 may include a first internal electrode 121 in contact with the first and third edge surfaces C1 and C3, and a second internal electrode 121 in contact with the second and fourth edge surfaces C2 and C4.

More specifically, the first internal electrode 121 may have an edge surface 121c1 of the first internal electrode disposed to be in contact with the first edge surface C1 of the body, an edge surface 121c2 of the first internal electrode disposed to be spaced apart from the second edge surface C2 of the body, an edge surface 121c3 of the first internal electrode disposed to be in contact with the third edge surface C3 of the body, and an edge surface 121c4 of the first internal electrode disposed to be spaced apart from the fourth edge surface C4 of the body.

In addition, the second internal electrode 122 may have an edge surface 122c1 of the second internal electrode disposed to be spaced apart from the first edge surface C1 of the body, an edge surface 122c2 of the second internal electrode disposed to be in contact with the second edge surface C2 of the body, an edge surface 122c3 of the second internal electrode disposed to be spaced apart from the third edge surface C3 of the body, and an edge surface 122c4 of the second internal electrode disposed to be in contact with the fourth edge surface C4 of the body.

In this case, the first and third external electrodes 131 and 133 may be respectively disposed on the first and third edge surfaces C1 and C3 of the body to be respectively connected to the first and third edge surfaces 121c1 and 121c3 of the first internal electrode, and second and fourth external electrodes 132 and 134 may be respectively disposed on the second and fourth edge surfaces C2 and C4 of the body to be respectively connected to the second and fourth edge surfaces 122c2 and 122c4 of the second internal electrode.

That is, the first internal electrode 121 may not be connected to the second and fourth external electrodes 132 and 134, but may be connected to the first and third external electrodes 131 and 133, and the second internal electrode 122 may not be connected to the first and third external electrodes 131 and 133, but may be connected to the second and fourth external electrodes 132 and 134.

In other words, the first and third edge surfaces 121c1 and 121c3 of the first internal electrode may be respectively in contact with the first and third edge surfaces C1 and C3, and may be respectively exposed to the first and third edge surfaces C1 and C3. However, the first and third edge surfaces 121c1 and 121c3 of the first internal electrode may be spaced apart from the third to sixth surfaces 3, 4, 5, and 6 and the second and fourth edge surfaces C2 and C4. The second and fourth edge surfaces 122c2 and 122c4 of the second internal electrode may be in contact with the second and fourth respectively edge surfaces C2 and C4, and may be respectively exposed to the second and fourth edge surfaces C2 and C4. However, the second and fourth edge surfaces 122c2 and 122c4 of the second internal electrode may be spaced apart from the third to sixth surfaces 3, 4, 5, and 6 and the first and third edge surfaces C1 and C3.

With respect to the cross-section of the body 110 in the second and third directions, when a length of each of the edge surfaces C1, C2, C3, and C4 is BL and a length of each of the internal electrodes 121 and 122 in contact with the edge surfaces C1, C2, C3, and C4 is BL, IEL<BL may be satisfied.

For example, the first and third edge surfaces 121c1 and 121c3 of the first internal electrode may be respectively in contact with the first and third edge surfaces C1 and C3 of the body. When the first edge surface C1 is BL and a length of the first edge surface 121c1 of the first internal electrode is IEL, IEL<BL may be satisfied. Such a configuration may be applied to a length of the third edge surface C3 of the body and a length of the third edge surface 121c3 of the first internal electrode in the same manner. Similarly, it will be obvious that such a configuration may be applied to the second internal electrode in the same manner.

That is, with respect to the cross-section of the body 110 in the second and third directions, a region of an internal electrode, exposed through an edge surface, may not be in contact with the entire edge surface, and may be in contact with only a portion of the edge surface.

A length (BL) of each of the edge surfaces C1, C2, C3, and C4, and a length (IEL) of each of the edge surfaces 121c1, 122c2, 121c3, and 122c4 of the internal electrode satisfy IEL<BL, such that regions of the internal electrodes 121 and 122 in contact with the external electrodes 131, 132, 133, and 134 may or may not include a minimum bottleneck portion, thereby improving equivalent series resistance (ESR) or equivalent series inductance (ESL). In addition, an external moisture permeation path may be lengthened, thereby improving moisture resistance reliability.

On the other hand, in the present invention, a bottleneck of an internal electrode may mean a shape in which the width or area of the internal electrode decreases from a center portion of the internal electrode to a region where the internal electrode contacts the external electrode in an internal electrode structure. In other words, the meaning of the internal electrode minimally including or not including a bottleneck may mean, but is not particularly limited to, a decrease in width or area of the internal electrode from a center portion of the internal electrode to a region where the internal electrode abuts the external electrode.

In addition, with respect to a cross-section of the body 110 in the second and third directions, the internal electrodes 121 and 122 may have a region, substantially parallel to the surfaces 3, 4, 5, and 6 of the body 110 adjacent to the edge surfaces C1, C2, C3, and C4 of the body 110 in contact with the internal electrodes 121 and 121.

For example, the first internal electrode 121 may be in contact with the first and third edge surfaces C1 and C3. In this case, the first internal electrode 121 may have a region spaced apart from the third and fifth surfaces 3 and 5 adjacent to the first edge surface C1, the region substantially parallel to the third and fifth surfaces 3 and 5, and may have a region spaced apart from the fourth and sixth surfaces 4 and 6 adjacent to the third edge surface C3, the region substantially parallel to the fourth and sixth surfaces 4 and 6.

In an example embodiment of the present disclosure, internal angles of the internal electrodes 121 and 122 may all be obtuse angles.

That is, the internal angles of the internal electrodes 121 and 122, formed by edges of the internal electrodes 121 and 122, may be greater than 90° and less than 180°.

The internal angles of the internal electrodes 121 and 122 may all be obtuse angles, such that regions of the internal electrodes 121 and 122 in contact with the external electrodes 131, 132, 133 and 134 may or may not include a minimum bottleneck portion. As a result, a current path may be improved, thereby improving ESR or ESL. In addition, the internal angles of the internal electrodes 121 and 122 may all be obtuse angles, such that spread of bleeding that may occur when an edge region is printed during coating of an internal electrode paste may be easily controlled. Accordingly, internal electrodes having a constant size and a constant shape may be coated, thereby easily performing control to minimize shape differences between the internal electrodes.

In addition, internal angles of a region in which the first and second internal electrodes 121 and 122 overlap each other may all be obtuse angles.

In other words, internal angles of the capacitance formation portion in which the first and second internal electrodes 121 and 122 overlap each other to form capacitance may all be obtuse angles, thereby minimizing a shape of a bottleneck portion of an internal electrode and maximizing an area forming capacitance. As a result, maximum capacitance in the same area may be easily designed.

The body 110 may be formed by alternately laminating a first ceramic green sheet on which a first internal electrode pattern is printed and a second ceramic green sheet on which a second internal electrode pattern is printed, and then performing sintering thereon. Here, the first and second internal electrode patterns may be formed by coating an internal electrode paste. After sintering is performed, the first and second internal electrode patterns may become the first and second internal electrodes 121 and 122.

In this case, the ceramic green sheets and the first and second internal electrode patterns may be partially removed, such that a dielectric layer and an internal electrode having octahedral shape may be manufactured, and a body having an octahedral shape may be manufactured.

FIG. 5A is a schematic design diagram of a cross-sectional view including a first internal electrode, and FIG. 5B is a schematic design diagram of a cross-sectional view including a second internal electrode.

FIGS. 5A and 5B for designing a dielectric layer and an internal electrode may be described as an example. First, with respect to FIG. 5A, a square may be set as a pattern in a first ceramic green sheet. When a size of one side of the square first ceramic green sheet is A1, a line (thick dotted line), connecting points respectively spaced apart by Ala from vertices of an edge region of the square first ceramic green sheet, may be removed to manufacture a first ceramic green sheet having an octahedral shape.

In this case, a distance from second and fourth vertices, adjacent to a third vertex, to a point of an edge region, adjacent to the third vertex, may be Alb, and a size of a sum of Ala and Alb may be A. In this case, Ala may be preferably manufactured to have a size of ⅓×A.

Before the edge region of the first ceramic green sheet is removed, two edge regions, opposing each other, among four edge regions (0.5×A1a×A1a) to be removed, for example, two edge regions including the first vertex and the third vertex may include a first internal electrode paste coated to be closer to the first and third vertices of the first ceramic green sheet, and remaining two edge regions, for example, two edge regions including the second vertex and the fourth vertex may include a first internal electrode paste coated to be further away from the second and fourth vertices of the first ceramic green sheet.

In other words, with respect to FIG. 5A, the first internal electrode paste may be coated to be close to the first and third vertices of the first ceramic green sheet, and may be coated to be away from the second and fourth vertices of the first ceramic green sheet.

The first internal electrode paste may be coated, as described. Thus, when the edge region of the first ceramic green sheet is removed, the first internal electrode may be exposed through the first and third edge surfaces of the body, and may not be exposed through the second and fourth edge surfaces of the body and may be spaced apart from the second and fourth edge surfaces of the body.

The first internal electrode paste may preferably be coated such that internal angles of the first internal electrode pattern are all obtuse angles, thereby minimizing a shape of a bottleneck portion of an internal electrode, and manufacturing the first internal electrode having the above-described shape.

For example, a square may be set as one virtual pattern in the first internal electrode pattern. In the same manner as the first ceramic green sheet described above, a virtual first internal electrode pattern may also include first to fourth vertices positioned in a clockwise direction from a left upper portion. When a size of one side of the virtual square first internal electrode pattern is B1, a first internal electrode paste may be coated such that the first internal electrode pattern has a shape in which points, respectively spaced apart by B1a from unexposed second and fourth vertices of the first internal electrode pattern of an edge region of the first internal electrode pattern, are connected each other. In this case, with respect to the first and third vertices of the virtual square first internal electrode pattern, a distance from points spaced apart by B1a from the second and fourth vertices of the virtual square first internal electrode pattern may be B1b, and a size of a sum of B1a and B1b may be B. In this case, B1a may be preferably manufactured to have a size of 0.3×B.

A method of forming the first ceramic green sheet and the first internal electrode pattern described above may be applied to a method of forming a second ceramic green sheet and a second internal electrode pattern in the same manner, and will be easily understood by those skilled in the art with reference to FIG. 5B symmetrically corresponding to FIG. 5A.

Here, a method of removing edge regions of the first and second internal electrode patterns, including the first and second ceramic green sheets, is not particularly limited, but may include removing a region to be removed using laser cutting or a blade. Alternatively, a scribing method may be used to scratch a line of an edge to be removed from a bar shape in which ceramic green sheets are laminated before sintering is performed, and then physically fracture the bar shape in a subsequent process.

A material, included in the internal electrodes 121 and 122, is not particularly limited, and any material having excellent electrical conductivity may be used. For example, the internal electrodes 121 and 122 may include at least one of nickel (Ni), copper (Cu), palladium (Pd), silver (Ag), gold (Au), platinum (Pt), tin (Sn), tungsten (W), titanium (Ti), and alloys thereof.

In addition, the internal electrodes 121 and 122 may be formed by printing, on a ceramic green sheet, an internal electrode conductive paste including at least one of nickel (Ni), copper (Cu), palladium (Pd), silver (Ag), gold (Au), platinum (Pt), tin (Sn), tungsten (W), titanium (Ti), and alloys thereof. A screen-printing method or a gravure-printing method may be used as a method of printing the internal electrode conductive paste, but the present disclosure is not limited thereto.

An average thickness of each of the internal electrodes 121 and 122 is not particularly limited.

In order to more easily achieve high capacitance and miniaturization of a multilayer electronic component, the average thickness of each of the internal electrodes 121 and 122 may be 1.0 μm or less, preferably 0.6 μm or less, and more preferably 0.4 μm or less.

The thickness of each of the internal electrodes 121 and 122 may refer to a size of each of the internal electrodes 121 and 122 in the first direction. In addition, the thickness of each of the internal electrodes 121 and 122 may refer to an average thickness of each of the internal electrodes 121 and 122, and may refer to an average size of each of the internal electrodes 121 and 122 in the first direction.

The average size of each of the internal electrodes 121 and 122 in the first direction may be measured by scanning, with an SEM, an image of a cross-section of the body 110 in the first and second directions at a magnification of 10,000. More specifically, the average size of each of the internal electrodes 121 and 122 in the first direction may refer to an average value of sizes of one internal electrode in the first direction, measured at thirty points equally spaced apart from each other in the second direction, in the scanned image. The thirty equally spaced points may be designated in the capacitance formation portion. In addition, when such average value measurement is performed on ten internal electrodes 121 and 122, the average size of each of the internal electrodes 121 and 122 in the first direction may be further generalized.

The body 110 may include cover portions 112 and 113 disposed on both end-surfaces of the capacitance formation portion in the first direction.

More specifically, the body 110 may include a first cover portion 112 disposed on one surface of the capacitance formation portion in the first direction, and a second cover portion 113 disposed on the other surface of the capacitance formation portion in the first direction, or may include an upper cover portion 112 disposed on an upper portion of the capacitance formation portion in the first direction, and a lower cover portion 113 disposed on a lower portion of the capacitance formation portion in the first direction.

The upper cover portion 112 and the lower cover portion 113 may be formed by respectively laminating a single dielectric layer 111 or two or more dielectric layers 111 on upper and lower surfaces of the capacitance formation portion in the first direction, and may basically serve to prevent damage to the internal electrodes 121 and 122 caused by physical or chemical stress.

The upper cover portion 112 and the lower cover portion 113 may not include the internal electrodes 121 and 122, and may include a material the same as that of the dielectric layer 111. That is, the upper cover portion 112 and the lower cover portion 113 may include a ceramic material, for example, a barium titanate (BaTiO₃)-based ceramic material.

An average thickness of each of the cover portions 112 and 113 is not particularly limited.

In order to more easily achieve high capacitance and miniaturization of a multilayer electronic component, the average thickness of each of the cover portions 112 and 113 may be 100 μm or less, preferably 30 μm or less, and more preferably 20 μm or less in an ultra-small product.

The thickness of each of the cover portions 112 and 113 may refer to a size of each of the cover portions 112 and 113 in the first direction. In addition, the thickness of each of the cover portions 112 and 113 may refer to an average thickness of each of the cover portions 112 and 113, and may refer to an average size of each of the cover portions 112 and 113 in the first direction.

The average size of each of the cover portions 112 and 113 in the first direction may be measured by scanning, with an SEM, an image of a cross-section of the body 110 in the first and second directions at a magnification of 10,000. For example, the average size of each of the cover portions 112 and 113 in the first direction may refer to an average value of sizes of the first cover portion 112 in the first direction, measured at thirty points equally spaced apart from each other in the second direction, in the scanned image.

In addition, an average size of the first cover portion 112 in the first direction, measured using the above-described method, may be substantially the same as an average size of the first cover portion 112 in the first direction with respect to a cross-section of the body 110 in the first and third directions.

In an example embodiment of the present disclosure, a structure in which a ceramic electronic component 100 has four external electrodes 131, 132, 133, and 134 is described, but the number, shape, or the like of the external electrodes 131, 132, 133, and 134 may vary depending on a form of the internal electrodes 121 and 122 or other purposes.

The external electrodes 131, 132, 133, and 134 may be disposed on the body 110 to be connected to the internal electrodes 121 and 122.

The external electrodes 131, 132, 133, and 134 may include a first external electrode 131, a second external electrode 132, a third external electrode 133, and a fourth external electrode 134, and may be disposed on the body 110 to be spaced apart from each other.

More specifically, the first external electrode 131 may be disposed on the first edge surface C1 to be in contact with the first internal electrode 121, the second external electrode 132 may be disposed on the second edge surface C2 to be in contact with the second internal electrode 122, the third external electrode 133 may be disposed on the third edge surface C3 to be in contact with the first internal electrode 121, and the fourth external electrode 134 may be disposed on the fourth edge surface C4 to be in contact with the second internal electrode 122.

In this case, the first external electrode 131 may entirely cover the first edge surface C1 and may be disposed on a portion of the third and fifth surfaces 3 and 5, the second external electrode 132 may entirely cover the second edge surface C2 and may be disposed on a portion of the fourth and fifth surfaces 4 and 5, the third external electrode 133 may entirely cover the third edge surface C3 and may be disposed on a portion of the fourth and sixth surfaces 4 and 6, and the fourth external electrode 134 may entirely cover the fourth edge surface C4 and may be disposed on a portion of the third and sixth surfaces 3 and 6.

The external electrodes 131, 132, 133, and 134 may be formed of any material having electrical conductivity, such as a metal or the like, and a specific material may be determined in consideration of electrical properties, structural stability, and the like. Furthermore, the external electrodes 131, 132, 133, and 134 may have a multilayer structure.

For example, the external electrode may include an electrode layer disposed on the body 110, and a plating layer formed on the electrode layer.

As a more specific example of the electrode layer, the electrode layer may be a sintered electrode including a conductive metal and glass, or a resin-based electrode including a conductive metal and a resin.

In addition, the electrode layer may have a form in which the sintered electrode and the resin-based electrode are sequentially formed on the body 110.

In addition, the electrode layer may be formed by transferring a sheet including a conductive metal onto the body 110 or by transferring a sheet including a conductive metal onto the sintered electrode.

The conductive metal used for the electrode layer is not particularly limited as long as it is a material capable of being electrically connected to the internal electrodes 121 and 122 to form capacitance. For example, the conductive metal may include at least one selected from the group consisting of nickel (Ni), copper (Cu), palladium (Pd), silver (Ag), gold (Au), platinum (Pt), tin (Sn), tungsten (W), titanium (Ti), and alloys thereof.

The electrode layer may be formed by applying a conductive paste prepared by adding a glass frit to the conductive metal powder particles and then sintering the conductive paste.

The plating layer may serve to improve mounting properties.

A type of the plating layer is not particularly limited, and may be a single plating layer including at least one of nickel (Ni), tin (Sn), palladium (Pd), and alloys thereof, and may be formed as a plurality of plating layers.

As a more specific example of the plating layer, the plating layer may be a Ni plating layer or a Sn plating layer, may have a form in which a Ni plating layer and a Sn plating layer are sequentially formed on the electrode layer, and may have a form in which a Sn plating layer, a Ni plating layer, and a Sn plating layer are sequentially formed.

In addition, the plating layer may include a plurality of Ni plating layers and/or a plurality of Sn plating layers.

A size of the multilayer electronic component 100 is not particularly limited.

In addition, in order to simultaneously achieve an effect of reducing low ESL, an effect of improving moisture resistance reliability and mechanical strength, and convenience in measuring capacitance in a high-frequency region, the multilayer electronic component 100 may have a size of 0606 (length×width: 0.6 mm×0.6 mm) or less, and may have a length (a size in the second direction) and a width (a size in the third direction), substantially the same. The multilayer electronic component 100, having a form-factor shape having an ultra-small size, may have a more significant effect according to the present disclosure.

Here, substantially the same length and width may not mean that a length and a width are completely the same, but may include an allowable error range. The substantially the same length and width may preferably mean that a difference between the length and the width is 10% or less, and more preferably, the difference between the length and the width is 5% or less. When the length and the width are substantially the same, a current loop may be improved, and the multilayer electronic component 100 having low ESL may be more easily achieved.

### Board Having Multilayer Electronic Component Mounted Thereon

MLCCs also have been widely used for decoupling that removes noise from electrical signals within a set due to low equivalent series inductance (ESL), excellent high-frequency properties.

In order to address noise in high-speed integrated circuits (ICs), land surface capacitors (LSCs) may be applied to portions adjacent to the ICs. It is known that an LSC requires low thickness and high-frequency properties. In order to reduce ESL, it is important to minimize the number of magnetic flux linkages per unit current in a high-frequency region. Such an issue has been addressed in various manners, such as controlling the formation and structure in a way that minimizes a current path or a current loop, or disposing internal and external electrodes in a manner cancelling a magnetic field.

In general, LSCs may be disposed on a lower portion of an IC board, and thus may be required to have low thickness and low ESL properties. In this case, LSCs may be mounted in a position in which a solder ball on a lower portion of a board is removed. Low inductance ceramic capacitors (LICCs) have mainly been used. However, there is increasing need for capacitors having a square form-factor.

Accordingly, in the present disclosure, a structure capable of achieving low ESL may be designed to include a body, having an octahedral shape, and a multilayer electronic component, thereby minimizing a current path to improve ESR and ESL properties, and to minimize a solder ball SOL to be removed, resulting in an advantageous design structure when mounted on a board.

Hereinafter, a board having a multilayer electronic component mounted thereon will be described. However, a description the same as the above description of the multilayer electronic component will be omitted.

A board having a multilayer electronic component thereon according to another example embodiment of the present disclosure, the board may include a printed circuit board, a multilayer electronic component disposed on the printed circuit board, and a solder ball SOL disposed on the printed circuit board, the solder ball SOL surrounding the multilayer electronic component 100. The multilayer electronic component 100 may include a body 110 including a dielectric layer 111 and internal electrodes 121 and 122 disposed alternately with the dielectric layer 111 in a first direction, the body 110 having first and second surfaces 1 and 2 opposing each other in the first direction, third and fourth surfaces 3 and 4 opposing each other in a second direction, perpendicular to the first direction, and fifth and sixth surfaces 5 and 6 opposing each other in a third direction, perpendicular to the first and second directions, the body 110 having a first edge surface C1 connected to the first to third and fifth surfaces 1, 2, 3, and 5, a second edge surface C2 connected to the first, second, fourth and fifth surfaces 1, 2, 4, and 5, a third edge surface C3 connected to the first, second, fourth and sixth surfaces 1, 2, 4, and 6, the third edge surface C3 opposing the first edge surface C1, and a fourth edge surface C4 connected to the first, second, third and sixth surfaces 1, 2, 3, and 6, the fourth edge surface C4 opposing the second edge surface C2, and external electrodes 131 and 132 disposed on the body 110. The internal electrodes 121 and 122 may include a first internal electrode 121 in contact with the first and third edge surfaces C1 and C3, and a second internal electrode 122 in contact with the second and fourth edge surfaces C2 and C4, and the external electrodes 131, 132, 133, and 134 may include first and third external electrodes 131 and 133 respectively disposed on the first and third edge surfaces C1 and C3, the first and third external electrodes 131 and 133 in contact with the first internal electrode 121, and second and fourth external electrodes 132 and 134 respectively disposed on the second and fourth edge surfaces C2 and C4, the second and fourth external electrodes 132 and 134 in contact with the second internal electrode 122.

Referring to FIG. 6, the multilayer electronic component 100 having an octahedral shape according to an example embodiment of the present disclosure may minimize removal of the solder ball SOL, as compared to a multilayer electronic component having a hexahedral shape according to the related art. The solder ball SOL may be further disposed in an edge region having a hexahedral shape according to the related art, thereby easily designing the multilayer electronic component 100.

In addition, by disposing the multilayer electronic component 100 having an octahedral shape as an LSC on the board, a size and an area of the solder ball SOL can be minimized, and a packaging board may be implemented to have fine ball grid array (BGA) pitch and height properties, thereby implementing excellent thermal properties and improving low ESL properties.

While example embodiments have been shown and described above, it will be apparent to those skilled in the art that modifications and variations could be made without departing from the scope of the present disclosure as defined by the appended claims.

In addition, the term “an example embodiment” used herein does not refer to the same example embodiment, and is provided to emphasize a particular feature or characteristic different from that of another example embodiment. However, example embodiments provided herein are considered to be able to be implemented by being combined in whole or in part one with one another. For example, one element described in a particular example embodiment, even if it is not described in another example embodiment, may be understood as a description related to another example embodiment, unless an opposite or contradictory description is provided therein.

The terms used herein is for the purpose of describing particular example embodiments only and is not to be limiting of the example embodiments. As used herein, the singular forms “a,” “an,” and “the” are intended to include the plural forms as well, unless the context clearly indicates otherwise.

What is claimed is:

1. A multilayer electronic component comprising:
a body including a dielectric layer and an internal electrode disposed alternately with the dielectric layer in a first direction, the body having first and second surfaces opposing each other in the first direction, third and fourth surfaces opposing each other in a second direction, crossing the first direction, and fifth and sixth surfaces opposing each other in a third direction, crossing the first and second directions, the body having a first edge surface connected to the first to third and fifth surfaces, a second edge surface connected to the first, second, fourth and fifth surfaces, a third edge surface connected to the first, second, fourth and sixth surfaces and opposing the first edge surface, and a fourth edge surface connected to the first, second, third and sixth surfaces and opposing the second edge surface; and
an external electrode disposed on the body,
wherein the internal electrode includes a first internal electrode in contact with the first and third edge surfaces, and a second internal electrode in contact with the second and fourth edge surfaces, and
the external electrode includes first and third external electrodes respectively disposed on the first and third edge surfaces to be in contact with the first internal electrode, and second and fourth external electrodes respectively disposed on the second and fourth edge surfaces to be in contact with the second internal electrode.

2. The multilayer electronic component of claim 1, wherein with respect to a cross-section of the body in the second and third directions, the first to fourth edge surfaces cross the second and third directions, respectively.

3. The multilayer electronic component of claim 1, wherein the first internal electrode is spaced apart from the third to sixth surfaces and the second and fourth edge surfaces, and
the second internal electrode is spaced apart from the third to sixth surfaces and the first and third edge surfaces.

4. The multilayer electronic component of claim 1, wherein with respect to a cross-section of the body in the second and third directions, a length BL of one of the first to fourth edge surfaces and a length IEL of the internal electrode in contact with the one of the first to fourth edge surfaces satisfy IEL<BL.

5. The multilayer electronic component of claim 1, wherein with respect to a cross-section of the body in the second and third directions, the internal electrode has a region, substantially parallel to a surface of the internal electrode adjacent to an edge surface in contact with the body.

6. The multilayer electronic component of claim 1, wherein the internal electrode does not have a region having a substantially decreasing width.

7. The multilayer electronic component of claim 1, wherein internal angles of the internal electrode are all obtuse angles.

8. The multilayer electronic component of claim 1, wherein with respect to an overlay view in the first direction, internal angles of a region in which the first and second internal electrodes overlap each other are all obtuse angles.

9. The multilayer electronic component of claim 1, wherein the first external electrode covers a portion of the third surface and a portion of the fifth surface,
the second external electrode covers a portion of the fourth surface and a portion of the fifth surface,
the third external electrode covers a portion of the fourth surface and a portion of the sixth surface, and
the fourth external electrode covers a portion of the third surface and a portion of the sixth surface.

10. The multilayer electronic component of claim 9, wherein each of the first to fourth external electrodes covers a portion of the first surface and a portion of the second surface.

11. The multilayer electronic component of claim 1, wherein the second direction is perpendicular to the first direction, and the third direction is perpendicular to the first and second directions.

12. A board having a multilayer electronic component mounted thereon, the board comprising:
a printed circuit board;
a multilayer electronic component disposed on the printed circuit board; and
a solder ball disposed on the printed circuit board, the solder ball surrounding the multilayer electronic component,
wherein the multilayer electronic component includes:
a body including a dielectric layer and an internal electrode disposed alternately with the dielectric layer in a first direction, the body having first and second surfaces opposing each other in the first direction, third and fourth surfaces opposing each other in a second direction, crossing the first direction, and fifth and sixth surfaces opposing each other in a third direction, crossing the first and second directions, the body having a first edge surface connected to the first to third and fifth surfaces, a second edge surface connected to the first, second, fourth and fifth surfaces, a third edge surface connected to the first, second, fourth and sixth surfaces and opposing the first edge surface, and a fourth edge surface connected to the first, second, third and sixth surfaces and opposing the second edge surface; and
an external electrode disposed on the body,
the internal electrode includes a first internal electrode in contact with the first and third edge surfaces, and a second internal electrode in contact with the second and fourth edge surfaces, and
the external electrode includes first and third external electrodes respectively disposed on the first and third edge surfaces to be in contact with the first internal electrode, and second and fourth external electrodes respectively disposed on the second and fourth edge surfaces to be in contact with the second internal electrode.
